(19) United States
(12) Patent Application Publication
(10) Pub. No.: US 2009/0051043 A1
(43) Pub. Date: Feb. 26, 2009

(54) DIE STACKING IN MULTI-DIE STACKS USING DIE SUPPORT MECHANISMS

(75) Inventors: Wai Loon Wong, Ipoh (MY); Cheng Sim Kee, Penang (MY); Nguk Chin Lai, Penang (MY); Poh Huat Teh, Penang (MY); Kwet Nam Wong, Penang (MY); Nutcha Tapamnuay, San Jose, CA (US); Bharatwaj Ramakrishnan, Sunnyvale, CA (US)

Correspondence Address: AMIN, TUROCY & CALVIN, LLP, 127 Public Square, 57th Floor, Key Tower, CLEVELAND, OH, 44114, US

(73) Assignee: SPANSION LLC, Sunnyvale, CA (US)

(21) Appl. No.: 11/842,655

(22) Filed: Aug. 21, 2007

(51) Int. Cl. H01L 23/49; H01L 21/66; H01L 21/67

(52) U.S. Cl. 257/777; 29/25.01; 438/15; 257/E21.53; 257/E23.024

(57) ABSTRACT

Systems, methods, and devices that facilitate stacking dies in a multi-die stack using die support mechanisms (DSMs) are presented. DSMs are employed to place a smaller die and attached wires underneath a larger die. DSMs can be placed on each side of the smaller die where the larger die overhangs when placed above the smaller die. The DSMs can be optimally sized to provide support to the larger die to reduce overhang and sagging, while providing a buffer region to protect the smaller die and associated wires. DSMs are employed to facilitate stacking dies that are the same or similar in size by placing a DSM between the dies. The DSM can be optimally sized to provide a buffer region to protect the wires bonded to the top side of the lower die from the upper die, while minimizing overhang to provide support to the upper die.

### BACKGROUND

The increase in density of semiconductor devices in recent years has resulted in the creation of multi-chip semiconductor devices that can contain multiple active dies or chips in a single device, where the dies can be stacked vertically on top of one another and connected electrically to a substrate, thereby increasing the number of electronic components (e.g., transistors) that can be included in a single chip package.

To further increase chip density, die thickness may also be decreased. However, certain issues can be raised due to the use of thinner dies as well as die overhang, such as when a larger die is stacked on top of a smaller die and part of the larger die extends beyond the surface area of the smaller die. For example, there can be wirebonding issues, such as die chipping or breaking, wire breaking, the failure of wires to stick to the die. Such wirebonding issues can be due to the upper die “bouncing” when wires are being connected to an upper die that overhangs when stacked on top of a smaller, lower die, for example. In addition, wirebonding issues can also arise when two dies that are of significantly different size are to be stacked together in the same chip package. For example, if a smaller die is stacked on a significantly larger die, the wires going from the substrate to the smaller die may have to be longer than desired, due to the size of the lower, larger die, which can result in wirebonding issues such as wire breakage and/or short circuiting, as may be caused by a shock force to the device.

Issues can also arise with wirebonding where a die is stacked on top of another die that is the same or similar in size. For example, if the upper die is the same or similar in size, then the wirebonding of the lower die can be problematic because the upper die can damage the wirebonding when it is stacked on top of the lower die, since the similar sizes of the dies can result in insufficient area being available to attach the wires to pads on the top (active) surface of the lower die.

It is desirable to be able to minimize or reduce wirebonding issues, die chipping or breaking issues, spatial issues, as well as other issues, associated with multi-die stacks, particularly with regard to thin dies, dies of the same or similar size stacked adjacent to each other, and/or dies that have significantly different sizes stacked adjacent to each other.

### SUMMARY

The following presents a simplified summary of the innovation in order to provide a basic understanding of some aspects described herein. This summary is not an extensive overview of the disclosed subject matter. It is intended to neither identify key or critical elements of the disclosed subject matter nor delineate the scope of the subject innovation. Its sole purpose is to present some concepts of the disclosed subject matter in a simplified form as a prelude to the more detailed description that is presented later.

The disclosed subject matter relates to systems and/or methods for stacking dies in a multi-die chip package using die support mechanisms (DSMs) as well as multi-die chip devices that can include DSMs. In accordance with one aspect of the disclosed subject matter, a larger die can be placed directly above a smaller die in a multi-die stack by employing DSMs that can facilitate wirebonding of the smaller die, while also providing desired support to the larger die, which, for example, can be attached to the DSMs that can be adhered to portions of the bottom side of the larger die that overhang beyond the smaller die. The DSMs can be formed from a blank (e.g., non-active) silicon wafer, film, or other type of material that can be used as a spacer to create the desired space between the active dies. A first die can be attached to a substrate or another component (e.g., another die). A second die that can be larger than the first die can be placed above the smaller die in the multi-die stack. Since a larger die can have significant overhang (e.g., the area of the larger die that extends beyond the surface area of the smaller die), DSMs can be employed, where a DSM can be placed adjacent to each side of the smaller die where the bottom side of the larger die (e.g., second die) overhangs. The size of the DSMs can be optimized such that wirebonding of the smaller first die can be facilitated while also providing desired support to the larger second die to minimize overhang as well as sagging of the second die in the middle region of the second die. Further, the height (e.g., thickness) of the DSMs can be optimized so as to provide a buffer region between the bottom side of the second die and the highest portion of the wires bonded to the first die, to minimize or reduce wire breaking issues, while keeping the DSM height to a minimum to conserve chip package space.

In accordance with another aspect of the disclosed subject matter, additional active dies can be stacked on top of the first and second dies. For example, a third die and fourth die can be included in the multi-die stack. In accordance with one aspect, the third die and fourth die can be the same or similar in size to each other and can be stacked adjacent to each other (e.g., fourth die stacked above the third die) by employing a DSM (e.g., spacer, silicon spacer, spacer film). By employing such DSM, wirebonding of the third die and fourth die can be facilitated and the desired support can be provided to the fourth die. For example, the third die can be adhered to the second die situated underneath the third die using die-attach film. Wirebonding of the third die can be performed to electrically connect wires to an active side (e.g., top side) of the third die, as desired. A DSM that can be a size (e.g., length, width) that is smaller than each of the third die and the fourth die can be attached to the active side of the third die. The size of the DSM can be such that it is small enough in length and/or width, so that the pads of the third die on which wires can be attached are exposed to facilitate bonding wires to the pads of the third die. The DSM can also be thick enough in height to facilitate wirebonding of the third die. The bottom side (e.g., non-active side) of the fourth die can then be adhered and/or attached to the top side of the DSM using die-attach film. The DSM can be large enough in size (e.g., length, width) to provide adequate support to the fourth die such that the portions of the fourth die that overhang can be minimized when attached to the top side of the DSM, while small enough in size to facilitate wirebonding of the third die. Further, the height (e.g., thickness) of the DSM can be optimized so as to provide a buffer region between the bottom side of the fourth die and the highest portion of the wires bonded to the third die, to minimize or reduce wire breaking issues, while keeping the DSM height to a minimum to conserve chip package space.

In accordance with yet another aspect of the disclosed subject matter, a die support component can facilitate generating DSMs. The die support component can analyze the respective sizes of the various dies and other components to be included in a multi-die stack as well as the relative positions of each of the dies and/or components. The die support component can then calculate a desired (e.g., optimal) size(s) of DSM(s) so as to facilitate wirebonding of the dies in the multi-die stack as well as provide desired support to a die(s), such as when a larger is placed directly above a smaller die and/or when two dies (e.g., active dies) are the same or similar in size and a DSM is placed therebetween. Once the size(s) of the DSM(s) is determined, the die support component can facilitate cutting one or more wafers to create the DSM(s) to be used in the multi-die stack that can be included in a semiconductor device, for example.

The following description and the annexed drawings set forth in detail certain illustrative aspects of the disclosed subject matter. These aspects are indicative, however, of but a few of the various ways in which the principles of the innovation may be employed and the disclosed subject matter is intended to include all such aspects and their equivalents. Other advantages and distinctive features of the disclosed subject matter will become apparent from the following detailed description of the innovation when considered in conjunction with the drawings.

### BRIEF DESCRIPTION OF THE DRAWINGS

FIG. 1 illustrates a cross-section diagram of a multi-die device in accordance with an embodiment of the disclosed subject matter.

FIG. 2 illustrates a cross-section diagram of a multi-die device in accordance with another embodiment of the disclosed subject matter.

FIG. 3 illustrates a block diagram of a system that facilitates forming a semiconductor device in accordance with the disclosed subject matter.

FIG. 4 illustrates a block diagram of a die support generation component in accordance with the disclosed subject matter.

FIG. 5 illustrates a methodology for attaching dies in accordance with the disclosed subject matter.

FIG. 6 illustrates a methodology for generating a die support in accordance with the disclosed subject matter.

FIG. 7 illustrates a methodology for stacking dies in accordance with an embodiment of the disclosed subject matter.

FIG. 8 illustrates another methodology for stacking dies in accordance with the disclosed subject matter.

FIG. 9 illustrates a methodology for generating and stacking dies in accordance with an embodiment of the disclosed subject matter.

FIG. 10 illustrates another methodology for generating and stacking dies in accordance with an embodiment of the disclosed subject matter.

### DETAILED DESCRIPTION

The disclosed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the disclosed subject matter may be practiced without these specific details. In other instances, well-known structures and devices are shown in block diagram form in order to facilitate describing the subject innovation.

The increase in density of semiconductor devices in recent years has resulted in the creation of multi-chip semiconductor devices that can contain multiple active dies or chips in a single semiconductor device, where dies can be stacked on top of each other thereby increasing the number of electronic components (e.g., transistors) that can be included in a single package. Issues (e.g., wire breakage, short circuiting of wires, chip warping, chip breakage, etc.) can arise when stacking dies, where, for example, an upper die is larger than a lower die such that the upper die has areas that overhang where the upper die is not supported, or when support is not provided in the center of the upper die, which may cause the upper die to sag. Conversely, issues (e.g., wire breakage, short circuiting of wires) can also arise where a smaller die is stacked on top of a larger die due to the length of the wires connecting the smaller die to the substrate. Further, stacking a die on top of another die where the dies are of the same or similar size can raise wirebonding issues, as the pads on which the wires are connected for the lower die can be covered by the upper die, since the dies are of the same or similar size.

Systems, methods, and devices relating to multi-die stacking are presented. The disclosed subject matter can employ die support mechanisms (DSMs) to place a smaller die (e.g., smaller in length and/or width), and wires bonded thereon, directly under a larger die, for example, by placing a DSM adjacent to each side of the smaller die where the larger die would otherwise overhang, and then attaching the larger die to the top side of each of the DSMs. The size(s) of the DSMs can optimized so that they facilitate wirebonding of the lower smaller die, while also providing the desired support to the larger upper die in overhanging areas as well as towards the center of the upper die to minimize or reduce sagging of the upper die. Further, a DSM can be employed to facilitate stacking dies of the same or similar size such that wirebonding of a die situated below another die of same or similar size can be facilitated while the DSM can also provide desired support to the die positioned above.

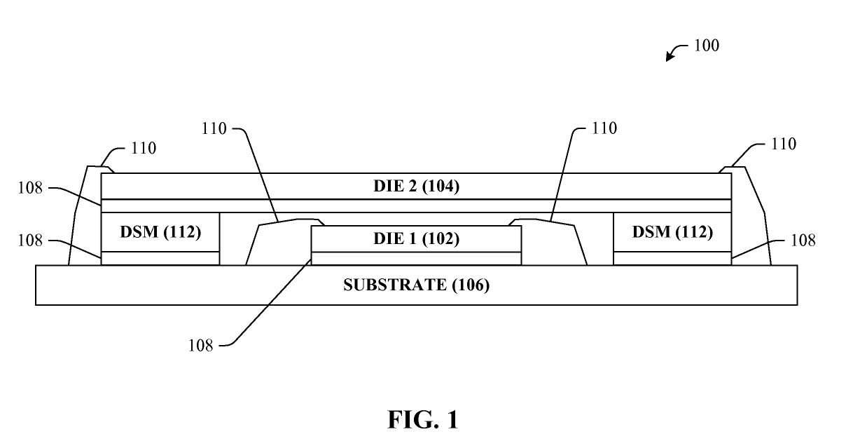

Now turning to the figures, FIG. 1 depicts a cross-section diagram of a multi-die device 100 in accordance with an embodiment of the disclosed subject matter. Device 100 can be a multi-die device that can include more than one die, where DSMs can be employed to facilitate stacking a larger die directly above a smaller die, for example. For example, device 100 can include a first die 102 and a second die 104 that each can be electrically connected to a substrate 106. It is to be appreciated that, while two dies are shown for example purposes, the disclosed subject matter is not so limited. The disclosed subject matter contemplates that any number of dies can be included in device 100. In accordance with an embodiment of the disclosed subject matter, the first die 102 can be smaller in size, such as in length and/or width, than the second die 104. Each die 102, 104 can be a semiconductor chip that can have an active side that can be electrically connected to the substrate 106 as well as a non-active side.

Substrate 106 can have traces (not shown) located on one side. The traces can be electrically conductive and can be formed on the substrate 106 by any suitable means, such as by etching processes (e.g., wet etching, dry etching, etc.) performed on the substrate surface or deposition processes (physical vapor deposition, chemical vapor deposition, electrochemical deposition, etc.).

Typically, when a larger die is stacked above a smaller die in a multi-die stack, the larger die can have regions that overhang where the second die extends beyond the surface area of the smaller die. If the larger die is relatively thin in thickness (e.g., 50 μm), and the amount of overhang is greater than 0.25 mm, there can be wirebonding issues with the larger die, such as broken wires, wires not bonding to the larger die, and/or die chipping or cracking, because the larger die can “bounce” during wirebonding due to lack of support in the areas where the larger die overhangs.

Device 100 facilitates providing support to areas of a larger die (e.g., second die 104) that overhang, including areas of the larger die 104 where the overhang is greater than 0.25 mm, so as to reduce or eliminate wirebonding issues associated with a larger die 104 stacked directly on top of a smaller die (e.g., first die 102), while facilitating wirebonding of the smaller die 102 as well.

Using die-attach film 108 that can be comprised of an insulating adhesive material (e.g., epoxy-based material), for example, the first die 102 can be laminated with the film 108 and can be adhered to the side of the substrate 106 having the traces formed thereon. The film 108 can be applied to the bottom (e.g., non-active side) of the first die 102, and the first die 102 can then be adhered to substrate 106. The first die 102 can be attached to the substrate 106 such that there are no gaps, or substantially no gaps, between the film 108 and the bottom side of first die 102 and between the film 108 and the top side of the substrate 106 and traces formed thereon. Applying the film 108 such that no gaps, or substantially no gaps, appear between the first die 102 and substrate 106 can reduce or eliminate delamination between the first die 102 and the substrate 106.

The first die 102 can have wires 110 bonded onto the die 102, as desired, to electrically connect the first die 102 to the substrate 106. The wires 110 can be formed of any suitable conductive material (e.g., gold). The desired number of wires 110 can be connected electrically to the substrate 106 by bonding one end of each of the wires 110 correspondingly to the desired traces on the substrate 106. The other end of each of the wires 110 can be bonded correspondingly to pads (not shown) on the active side of the first die 102.

To facilitate stacking the larger die 104 above the smaller die 102, device 100 can include DSMs 112 that can be employed to provide support to the second die 104 (e.g., larger die) in regions where the second die 104 may overhang or extend beyond the top surface of the smaller first die 102 as well as to provide a buffer region between the highest point of the wires 110 bonded to the first die 102 and the bottom side of the second die 104 in order to protect the wires 110 bonded to the first die 102. The DSMs 112 can be in the form of a blank silicon wafer (e.g., non-functional die with no active circuitry), film, and/or spacer, for example. The DSMs 112 can be placed adjacent to each side of the first die 102 where the second die 104 overhangs, as desired, thereby creating a bridge support for the second die 104 so the second die 104 can be bridged above and across the first die 102, and wires 110 bonded thereon.

The length and/or width of each DSM 112 can be optimized such that each DSM 112, when placed (e.g., attached) next to the smaller die 102, can be flush with an outer edge of the larger die 104, when attached, so that the larger die 104 can have no overhang, or substantially no overhang. Further, the DSM 112 can be sized such that it will not impact or damage the first die 102 or the wires 110 bonded to the first die 102. However, it can be desirable to make the DSMs 112 as large as possible, without impacting or damaging the first die 102 and wires 110 attached thereto, in order to provide support to the second die 104, particularly in the center of the second die 104, so as to minimize sagging of the second die 104. Further, each DSM 112 can have a thickness such that there can be a buffer region between the bottom side of the second die 104, which can be attached to each DSM 112, and the highest portion of the wires 110 bonded to the first die 102, while the DSM 112 can have a small enough thickness to minimize the amount of space taken by the DSM 112 in the chip package. By sizing the DSM 112 in such a manner, wire issues (e.g., breakage, shorting) can be reduced or eliminated, while conserving space in the chip package.

Thus, the size of the DSMs 112 can be based on various factors. For example, one factor can be the length and/or width of each die 102 and 104. Another factor can also be the respective position of each die 102 and 104. For example, it may be desirable to place the smaller die 102 off-center, for reasons, such as a more desirable circuit layout. In such an instance, the size of each DSM 112 may be different. Still another factor can be the amount of space desired in order to have desired wires 110 bonded to the first die 102, including the amount of headroom or buffer region between the larger die 104 and the wires 110 bonded to the first die 102, so such wires 110 are not impacted or damaged when the second die 104 is attached to the DSMs 112 on the die stack, as well as the amount of support provided to the second die 104 by the DSMs 112 so as to minimize sagging of the second die 104. At the same time, another factor that can be considered is the desired amount or acceptable amount of overhang for the second die 104 when the second die 104 is placed on the DSM 112 in the die stack, as minimizing die overhang can be desirable to minimize wirebonding issues and chipping and/or breaking of the second die 104, for example. In addition, other factors, such as the thickness of the film 108 and overall package height can be considered in determining the size of respective DSMs 112.

With DSMs 112 of a desired size, the DSMs 112 can have the bottom sides laminated with film 108, and the DSMs 112 can be attached to the substrate 106 (or other component on which the first die 102 is attached) in each area where the larger die 104 may overhang when placed on the die stack.

The larger die 104 can be adhered to the top sides of each of the DSMs 112 by laminating the bottom side (e.g., non-active side) of the larger die 104 with film 108 and attaching the larger die 104 to the DSMs 112. A desired number of wires 110 can then be bonded to pads (not shown) on the top side (e.g., active side) of the larger die 104. Those wires 110 can be electrically connected to the substrate 106.

Employing DSMs 112 to place the smaller die 102 under larger die 104 can facilitate wirebonding and reduce or minimize wire malfunctions (e.g., wire breaking, short circuits) and facilitate a more desirable circuit layout. For example, if the smaller die (e.g., 102) is stacked on top of a much larger die (e.g., 104), wirebonding issues may arise when wirebonding between the substrate 106 and the smaller die 102, since the wires 110 would have to extend from the substrate 106 over the larger die 104 and then extending across the larger die 104 to reach the pads of the smaller die 102. Instead, by placing the smaller die 102 and associated wires 110 under the larger die 104 can reduce the length of the wires 110 of the smaller die 102, which can reduce or minimize wire breakage and short circuits, for example.

It should be noted that, while device 100 is shown in FIG. 1 with one wire on each side of dies 102 and 104, each of dies 102 and 104 can have any desired number of wires 110. Further, while the wires 110 are shown on two sides of the dies 102 and 104, it is to be appreciated that each die 102, 104 can have pads on some or all sides of such die to facilitate wirebonding on some or all sides of the respective die. In addition, while first die 102 is shown as being attached to substrate 106 with film 108, it is to be appreciated that any number of additional dies can be employed, as desired. For example, first die 102 can be stacked on top of another die using film 108, and that other die can be attached to the substrate 106 using film 108. It should also be noted that well known structures (e.g., chip casing, etc.) have not been shown in order not to unnecessarily obscure the subject innovation.

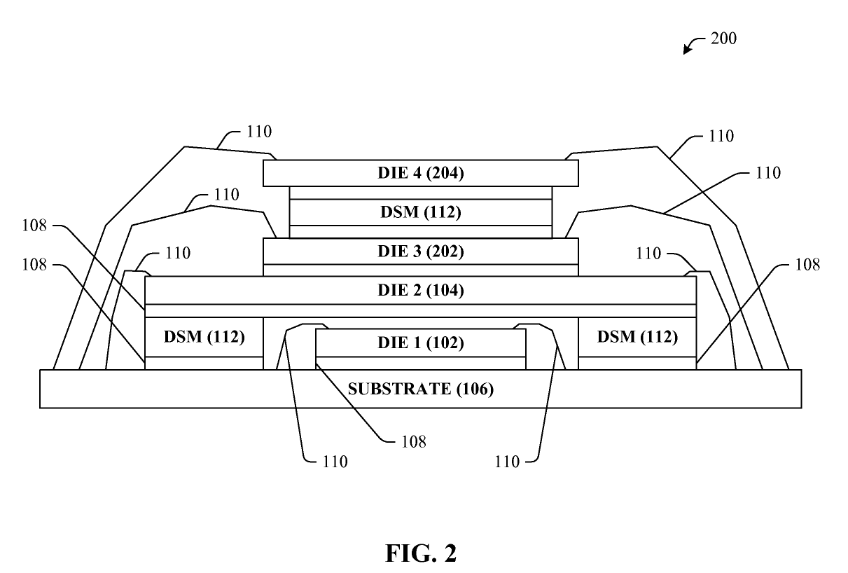

Turning to FIG. 2, illustrated is a cross-section diagram of a multi-die device 200 in accordance with another embodiment of the disclosed subject matter. Device 200 can be a multi-die device that can include more than one die. For example, device 200 can include a first die 102 and a second die 104 that each can be electrically connected to a substrate 106, and can be structured as more fully described with regard to device 100. Further, device 200 can include a third die 202 and fourth die 204. It is to be appreciated that, while four dies are shown for example purposes, the disclosed subject matter is not so limited. The disclosed subject matter contemplates that any number of dies can be included in device 200. In accordance with one embodiment of the disclosed subject matter, the third die 202 and fourth die 204 can be the same size, or substantially the same size, in length and/or width to each other. Each die 202, 204 can be a semiconductor chip that can have an active side and a non-active side.

As stated, device 200 can include the first die 102, which can be adhered to the substrate 106 in a same or similar manner as more fully described with regard to device 100. Further the second die 104 can be adhered to the first die 102 in a same or similar manner as more fully described with regard to device 100. Device 200 can include DSMs 112 that can be attached to the substrate 106 and next to the first die 102 in each area where the second die 104 overhangs beyond the top surface of the first die 102, where the DSMs 112 can be formed and attached to substrate 106 and second die 104 in a same or similar manner as more fully described with regard to device 100. The dimensions of the DSMs 112 can be such that the DSMs facilitate wirebonding of dies 102 and 104, as well as providing suitable support to the larger die 104, as more fully described with regard to device 100. Further, the dimensions of the DSMs 112 can be such that desired support can be provided to the second die 104 when additional dies, such as dies discussed more fully below, are stacked above the second die 104 in the die stack, so as to reduce or eliminate sagging of the second die 104 and/or the bouncing of the second die 104. Further, the first die 102 and second die 104 can each have wires 110 bonded thereon to electrically connect each die 102, 104 to the substrate 106, in a same or similar manner as more fully described with regard to device 100.

A third die 202 can be adhered to the top side of the second die 104 by laminating the third die 202 with die-attach film 108 that can be comprised of an insulating adhesive material (e.g., epoxy-based material), for example. The film 108 can be applied to the bottom side (e.g., non-active side) of the third die 202, and the third die 202 can then be adhered to second die 104. The film 108 can be applied and the die attached such that no gaps (e.g., voids, abscesses), or substantially no gaps, exist so as to reduce or eliminate delamination between the third die 202 and the second die 104.

A plurality of wires 110 can be employed to electrically connect the third die 202 to the substrate 106. The desired number of wires 110 can be connected electrically to the substrate 106 by bonding one end of each of the wires 110 correspondingly to the desired traces on the substrate 106. The other end of each of the wires 110 can be bonded correspondingly to pads (not shown) on the active side of the third die 202.

Device 200 can also include a DSM 112 that can be employed to provide a buffer space between the third die 202 and the fourth die 204 to facilitate wirebonding of the third die 202 and fourth die 204, while also providing desired support to the fourth die 204 that can be stacked on top of the DSM 112, as described more fully herein. The length and/or width of the DSM 112 can be optimized such that the DSM 112 is smaller in size than the third die 202 such that the wires 110 connected to the third die 202 are not impacted or damaged by the DSM 112, that is, the pads and wires of third die 202 are not covered by the DSM 112 when the DSM 112 is attached to the top side (e.g., active side) of third die 202; however, the DSM 112 also can be as large as possible, within the aforementioned constraint, so as to provide support for the fourth die 204 that can be attached to the top side of the DSM 112. Further, the DSM 112 can be a thickness such that there can be a buffer region between the bottom side of the fourth die 204 that can be attached to the DSM 112 and the highest portion of the wires 110 bonded to the third die 202, while the DSM 112 also can be a small enough thickness to minimize the space taken by the DSM 112 in the chip package. By sizing the DSM 112 in such a manner, wire issues (e.g., breakage, shorting) can be reduced or eliminated, while also conserving space in the chip package.

Thus, the size of the DSM 112 can be based on various factors. For example, one factor can be the length and/or width of the third die 202 and fourth die 204. Another factor can be the amount of space desired in order to have desired wires 110 bonded to the third die 202, including the amount of headroom or buffer region between the third die 202 and fourth die 204 so that the wires 110 bonded to the third die 202 are not impacted or damaged when the fourth die 204 is attached to the die stack as well as the amount of surface area of the third die 202 to remain exposed after attaching the DSM 112 to the third die 202 so that the pads thereon and/or wires 110 attached thereto are not impacted or damaged. Still another factor can be the desired amount or acceptable amount of overhang for the fourth die 204 when the fourth die 204 is placed on the DSM 112 in the die stack, as minimizing die overhang can be desirable to minimize wirebonding issues and chipping and/or breaking of the fourth die 104, for example. In addition, other factors, such as the thickness of the film 108 and overall package height can be considered in determining the size of respective DSMs 112.

With a DSM 112 of desired size, the bottom side of the DSM 112 can be laminated with film 108, for example. The bottom side of the DSM 112 can then be attached to the top side of the third die 202 such that the wirebonding of the third die 202 is not impacted or damaged.

After the DSM 112 is adhered and/or attached to the third die 202, the bottom side of the fourth die 204 can be attached to the top side of the DSM 112. The bottom side (e.g., non-active) of the fourth die 104 can be laminated with film 108 and can be attached to the top side of the DSM 112 such that the DSM 112 can provide the desired support to the fourth die 204, for example, by minimizing the amount of overhang, so that no one side has more overhang, or at least substantially more overhang, than its opposite side. The active side of the fourth die 204 can then be wirebonded with the desired number of wires 110 connected thereto, with the other end of each wire 110 connected to the substrate 106.

Device 200 and/or device 100 can be included in most any electronic device that includes a semiconductor chip package (e.g., device 200, device 100). Examples of such an electronic device can include a computer, a personal digital assistant (PDA), a cellular phone, a digital phone, an answering machine, a video device, a television, a digital versatile diskplayer/recorder, a music player/recorder, an MP3 player, a digital recorder, a digital camera, a microwave oven, an electronic organizer, an electronic toy, an electronic game, a scanner, a reader, a printer, a copy machine, or a facsimile machine.

Further, device 200 and/or device 100 can be a memory device, including non-volatile memory, such as flash memory, read only memory (ROM), programmable ROM (PROM), erasable programmable read only memory (EPROM), electronically erasable programmable read only memory (EEPROM), and the like; and volatile memory such as random access memory (RAM), including static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

It should be noted that, while device 200 is shown in FIG. 2 with one wire on each side of dies 102, 104, 202, and 204, each of dies 102, 104, 202, and 204 can have any desired number of wires 110. Further, while the wires 110 are shown on two sides of the dies 102, 104, 202, and 204, it is to be appreciated that each die 102, 104, 202, and 204 can have pads on some or all sides of the respective die to facilitate wirebonding on some or all sides of the respective die. In addition, while first die 102 is shown as being attached to substrate 106 with film 108, it is to be appreciated that additional dies can be employed, as desired. For example, first die 102 can be stacked on top of another die using film 108, and that other die can be attached to the substrate 106 using film 108. It should also be noted that well known structures (e.g., chip casing, etc.) have not been shown in order not to unnecessarily obscure the subject innovation.

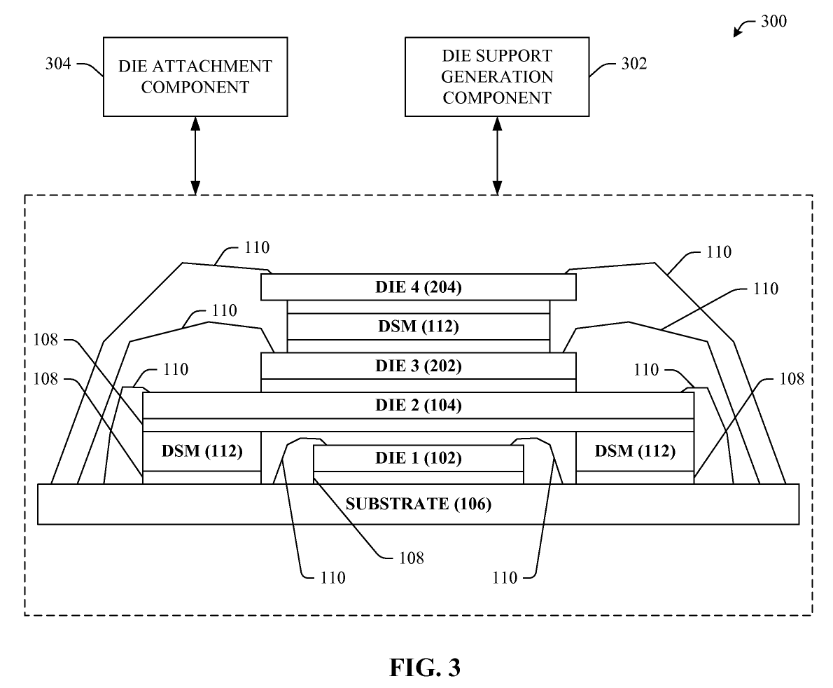

Turning to FIG. 3, illustrated is a block diagram of a system 300 that facilitates multi-die stacking in accordance with the disclosed subject matter. System 300 can include a substrate component 106 that can be a substrate that can have traces formed thereon, where the traces can be formed on the substrate component 106 as previously described herein. Substrate 106 can be associated with a die-attach film component 108 that can be a non-conductive adhesive material that be utilized to facilitate attaching a first die 102 to the substrate 106.

System 300 can also include a second die 104, third die 202, and fourth die 204. Each die 102, 104, 202, and 204 can have an active side and a non-active side, where pads (not shown) can be formed on the active side to facilitate wirebonding of each die to electrically connect each die to the substrate 106. Each die 102, 104, 202, and 204 and substrate 106 can be associated with wire component 110, which can be comprised of one or more wires, as desired, to electrically connect traces on substrate 106 to the pads formed on each die 102, 104, 202, and 204.

System 300 can include a die support generation component 302 (DSGC) that can facilitate generating one or more DSMs 112 (DSMs) that can be utilized to facilitate wirebonding, and/or maintaining wirebonding, of die components 102, 104, 202, and/or 204 as well as provide support to the second die 104 and/or fourth die 204. The DSMs 112 can be in the form of a blank silicon wafer (e.g., non-active die), film, and/or spacer, for example. The DSM 112 can be employed to provide a buffer space between the first die 102 and the second die 104 to facilitate wirebonding of each die 102, 104, 202, and 204, while also providing desired support to the second die 104 and/or fourth die 204. The size of a particular DSM 112 can be based on various factors, such as those described with regard to DSM 112 associated with device 200 and/or device 100.

In accordance with one embodiment of the disclosed subject matter, the first die 102 can be a die of smaller size (e.g., in length and/or width) and the second die 104 can be a die that can be larger in size than the first die 102. DSMs 112 can be utilized to facilitate placing the larger second die 104 above the smaller first die 102 in a multi-die stack, where the DSMs 112 can provide support to the second die 104 in regions where the second die 104 may overhang or extend beyond the surface of the smaller first die 102 as well as to provide a buffer region to protect the wires 110 bonded to the first die 102. For example, DSMs 112 can be placed on each side of the first die 102 where the second die 104 overhangs, as desired.

The length and/or width of each DSM 112 can be optimized such that each DSM 112, when placed (e.g., attached and/or adhered) next to the first die 102, can be flush with an outer edge of second die 104, when attached and/or adhered to the DSMs 112, so that the second die 104 can have no overhang, or substantially no overhang. Further, the DSMs 112 can be sized such that they will not impact or damage the first die 102 or the wires 110 bonded to the first die 102. However, at the same time, the DSMs 112 can be sized as large as possible, within the above constraint, in order to provide support to the larger second die 104, particularly in the center of the second die 112, so as to minimize sagging of the second die 104. Further, each DSM 112 can have a thickness such that there can be a buffer region between the bottom side of the second die 104, which can be attached to each DSM 112, and the highest height of the wires 110 bonded to the smaller first die 102, while the DSM 112 also can be small enough in height so as to minimize the amount of space taken by the DSM 112 in the chip package. By sizing the DSM 112 in such a manner, wire issues (e.g., breakage, shorting) can be reduced or eliminated, while conserving space in the chip package.

Further, a DSM 112 can facilitate stacking of a third die 202 and a fourth die 204 in the die stack, where such dies 202, 204 are the same or similar in size. The third die 202 can be laminated with film 108 and adhered to the top side of the second die 104. The third die 202 can be smaller in size than the second die 104, for example. After attaching the third die 202 to the second die 104, the fourth die 204 can be attached to the third die 202, which can be facilitated by employing a DSM 112 that can be placed in between the dies 202 and 204. Placing the DSM 112 in between the dies 202 and 204 can thereby facilitate wirebonding of the dies 202 and 204 as well as providing support to the fourth die 204. The length and width of the DSM 112 can be optimized such that the DSM 112 can be smaller in size than the third die 202 such that the wires 110 connected to the third die 202 are not impacted or damaged by the DSM 112. For example, DSM 112 can be sized such that the pads and wires 110 of the third die 202 are not covered by the DSM 112 when the DSM 112 is attached to the top side of the third die 202. At the same time, the DSM 112 also can be as large in size as possible, but within the aforementioned constraint, so as to provide desired support for the fourth die 204, the bottom side of which can be attached to the top side of DSM 112. Further, the DSM 112 can be a height such that there can be a buffer region between the bottom of the fourth die 204 that can be attached to the DSM 112 and the top portion of the wires 110 bonded to the third die 202, while DSM 112 also can be small enough in height so as to minimize the space taken by the DSM 112 in the multi-die chip package. By sizing the DSM 112 in such a manner, wire issues (e.g., breakage, shorting) can be reduced or eliminated, while also conserving space in the chip package.

Turning back to DSGC 302, component 302 can facilitate generating the DSMs 112 such that the DSMs 112 are of a desired size and number so as to facilitate wirebonding of the die components in the multi-die stack as well as provide desired support to any die component (e.g., 104, 204) attached to the top of the DSM(s) 112. The DSGC 302 can analyze the various components (e.g., substrate 106, the dies (e.g., 102, 104, 202, 204), film 108, wires 110, etc.) of system 300 to determine the respective sizes of the various components as well as the relative positions of each of the various components in the multi-die stack. For example, where a larger die component is positioned directly above a smaller die component in a multi-die stack, DSGC 302 can measure the amount of overhang the larger die component will have when placed above the smaller die component.

DSGC 302 can use the size and spatial determinations to calculate the number of DSMs 112 desired for the type of die stacking and the size(s) of a DSM(s) 112. For example, where the die components 202 and 204 are of the same or similar size, the DSGC 302 can determine that one DSM 112 is desired, and such DSM 112 can be positioned between the two die components 202 and 204. The DSGC 302 can determine a desired or optimal size of the DSM 112 so that wirebonding of the third die 202 is not impacted or damaged, and the wirebonding of the fourth die component 204 is facilitated and the fourth die 204 can be provided desired or optimal support by the DSM 112. DSGC 302 can have information regarding the amount of space desired so that the third die 202 can be wirebonded as well as information regarding the amount of overhang the fourth die 204 can have without having an unacceptable level of bounce, such as for during wirebonding of the fourth die 204.

As another example, where the first die 102 is smaller in size than the second die 104, and is to be placed under the second die 104, DSGC 302 can measure and determine the amount of overhang for each area the second die 104 overhangs when placed directly above the first die 102. Further, DSGC 302 can determine that more than one DSM 112 is desirable, since there can be more than one area of the second die 104 that can overhang when placed above the first die 102. DSGC 302 can determine that a DSM 112 should be placed near the first die 102 in regions where it is determined that the second die 104 will overhang when placed above the first die 102 in the multi-die stack. For example, two DSMs 112 can be employed if the second die 104 will overhang in two regions (e.g., second die 104 is larger in length or width), or four DSMs 112 can be employed if the second die 104 will overhang in four regions (e.g., second die 104 is larger in length and width than the first die 1023). In determining the desired number and size of the DSM(s) 112, the DSGC 302 can analyze the various factors, as described more fully herein with regard to device 200 and device 100.

DSGC 302 can further facilitate the generation of the desired number of DSMs 112 with each DSM 112 having the desired size. DSGC 302 can facilitate cutting DSMs 112 from blank wafers (e.g., silicon wafers) or other materials that can be utilized to provide a spacer(s) to facilitate the desired multi-die stack. The wafers or other materials can be cut or diced into the desired size in accordance with the size determinations made by the DSGC 302. The DSM(s) 112 generated by the DSGC 302 can then be utilized in the multi-die stack associated with system 300.

System 300 can further include a die attachment component 304 that can facilitate attachment of the dies 102, 104, 202, and/or 204, the substrate 106, and the DSMs 112 as well as other components, such as other die components (not shown), as desired, and as described herein. For example, to attach the first die 102 to the substrate 106, die attachment component 304 can facilitate applying the die-attach film 108 to the non-active side (e.g., bottom side) of the first die 102. The die attachment component 304 can attach the first die 102 to the substrate 106 such that there are no gaps, or substantially no gaps, between the first die 102 and the substrate 106, as the film 108 can fill in, or substantially fill in, all gaps between components 102 and 106.

It should be noted that, while system 300 is shown in FIG. 3 with four dies 102, 104, 202, and 204, the subject innovation is not so limited, as it can include more or less than four dies. Further, while system 300 is shown with one wire on each side of dies 102, 104, 202, and 204, each of dies 102, 104, 202, and 204 can have any desired number of wires 110. Further, while the wires 110 are shown on two sides of the dies 102, 104, 202, and 204, it is to be appreciated that each die 102, 104, 202, and 204 can have pads on some or all sides of the respective die to facilitate wirebonding on some or all sides of the respective die. In addition, while first die 102 is shown as being attached to substrate 106 with film 108, it is to be appreciated that additional dies can be employed, as desired. For example, first die 102 can be stacked on top of another die using film 108, and that other die can be attached to the substrate 106 using film 108. It should also be noted that well known components (e.g., chip casing, etc.) have not been shown in order not to unnecessarily obscure the subject innovation.

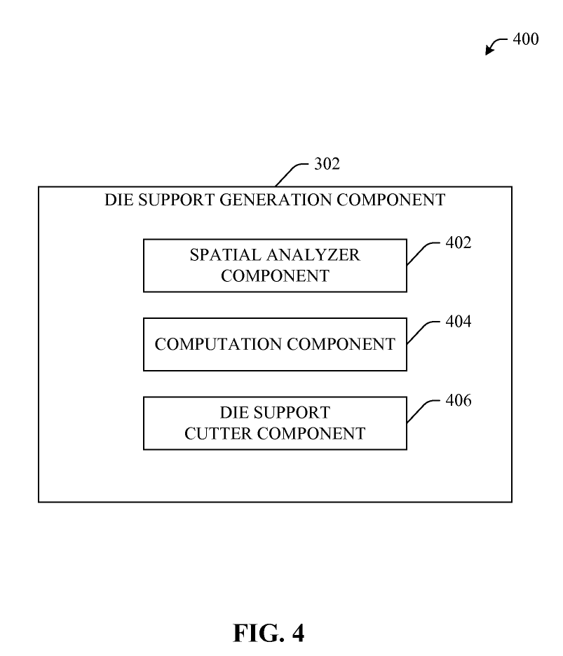

FIG. 4 is a block diagram 400 of a DSGC 302 in accordance with an embodiment of the disclosed subject matter. DSGC 302 can include a spatial analyzer component 402 that can analyze the spatial dimensions and relative positions of the various components (e.g., substrate 106, dies 102, 104, 202, 204, film 108, wires 110, etc.) associated with system 300. DSGC 302 also can include a computation component 404 that can utilize the information regarding the spatial dimensions and relative positions of such various components to calculate the number of DSMs 112 desired for the type of die stacking as well as the size(s) of each DSM 112. In determining the desired number and size of the DSM(s) 112, the computation component 404 can analyze various factors, such as those factors described more fully herein with regard to device 200 and device 100.

DSGC 302 can further include a die support cutter component 406 that can facilitate the generation of the desired number of DSMs 112 with each DSM 112 having the desired size. Die support cutter component 406 can facilitate cutting DSMs 112 from blank wafers (e.g., silicon wafers) or other materials that can be utilized to provide a spacer(s) to facilitate the desired multi-die stack. The wafers or other materials can be cut or diced into the desired size in accordance with the size determinations made by the computation component 404. The DSM(s) 112 generated by the die support cutter component 406 can then be utilized in the multi-die stack associated with system 300.

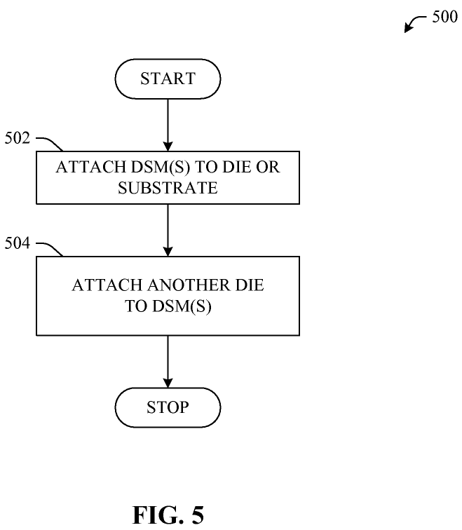

FIGS. 5-10 illustrate methodologies in accordance with the disclosed subject matter. For simplicity of explanation, the methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts may be required to implement the methodologies in accordance with the disclosed subject matter. In addition, those skilled in the art will understand and appreciate that the methodologies could alternatively be represented as a series of interrelated states via a state diagram or events. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

Referring to FIG. 5, a methodology 500 for facilitating die stacking in accordance with the disclosed subject matter is illustrated. At 502, one or more DSMs (e.g., 112) can be attached to a top side of a die or a substrate (e.g., 106), where the attachment can be facilitated using die-attach film (e.g., 108) that can on the bottom side of the DSM(s) and can adhere the bottom side of the DSM(s) to the top side of the die or substrate. At 504, a bottom side of another die (e.g., 104) can be attached to the top side(s) of the one or more DSMs, where the attachment can be facilitated using die-attach film that can on the bottom side of the other die and can adhere the bottom side of the other die to the top side of the DSM(s). The DSM(s) can be employed to provide a buffer space between a lower die and another die (e.g., die positioned above lower die in the die stack) to facilitate wirebonding of each die, while also providing desired support to the other die positioned above the lower die in the die stack. The size of a particular DSM can be based on various factors, such as those described with regard to DSM associated with device 200 and/or device 100.

For example, in certain instances the lower die (e.g., 102) in the die stack can be smaller in size (e.g., length and/or width) than the other die (e.g., 104) positioned directly above the lower die. In such instances, when the larger die is placed above the smaller die in the die stack, the larger die can have regions that overhang where that die extends beyond the surface area of the top of the smaller die. A desired number of DSMs can be employed to support each region of the larger die that overhangs beyond the smaller die. The desired number of DSMs can be attached to the substrate or another die to which a smaller die is attached, where the DSMs can be positioned so that the DSMs can provide support to the larger die where that die overhangs as well as to facilitate wirebonding of the dies.

As another example, in certain instances the dies (e.g., 202, 204) can be the same or similar size. In such instances, a DSM can be attached to the top side of the lower die. The bottom side of the upper die can then be attached to the top side of the DSM, such that the DSM can be between the lower die and upper die. At this point, methodology 500 can end.

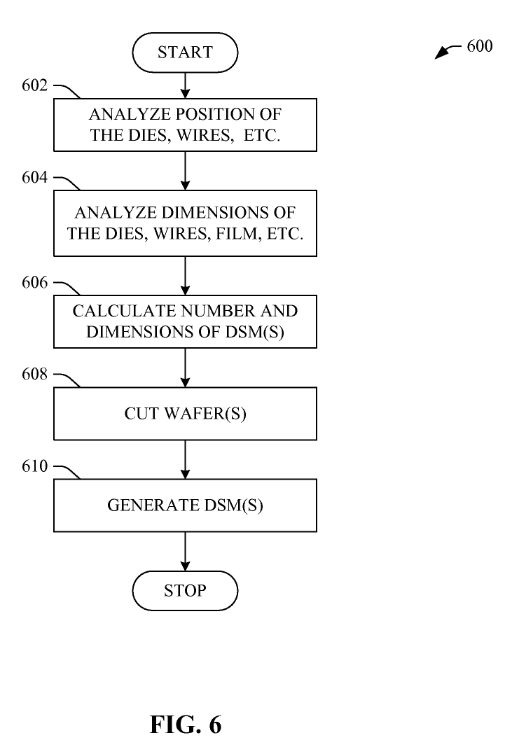

FIG. 6 illustrates a methodology 600 for generating a DSM(s) (e.g., 112) in accordance with an embodiment of the disclosed subject matter. At 602, the relative positions of each of the dies, wires, film, and other components associated with a multi-die chip package can be analyzed. At 604, the respective dimensions of each of the dies, wires, film, and other components associated with a multi-die chip package can be analyzed. The position and dimension information can be used, for example, to measure and determine the amount of overhang a larger die (e.g., larger in length and/or width) may have when placed directly above a smaller die in a die stack. Further, the thickness of a larger die can be measured so that it is known what amount of overhang, if any, can be acceptable. Further, such information can be used to determine the amount of space desired to wirebond a die when another die is stacked above the lower die.

At 606, the number of DSMs and the size of each DSMs can be calculated. The dimensions of each DSM can be determined based on various factors, such as those described herein with regard to device 200 and device 100, for example. At 608, one or more wafers (e.g., blank silicon wafer) or other suitable material can be cut to form one or more DSMs that can be the desired size in accordance with the dimensions calculated at 606. At 608, the desired number of DSMs, each having the desired dimensions, can be generated. At this point, methodology 600 can end.

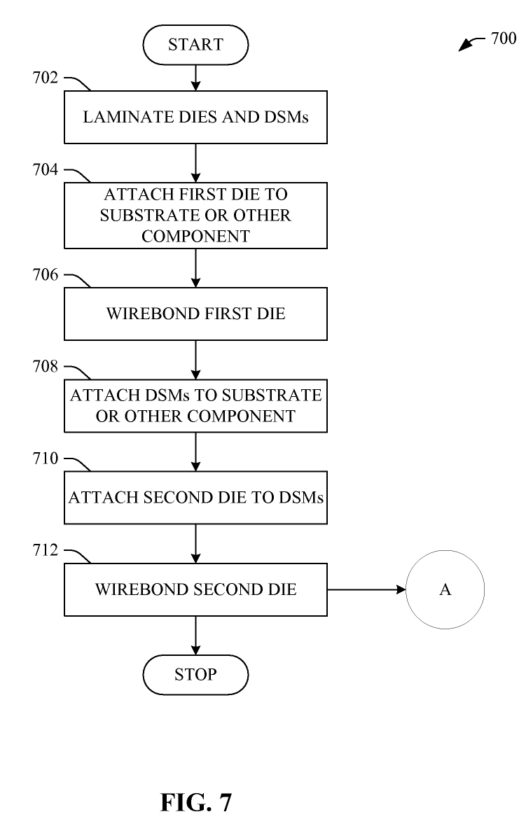

FIG. 7 depicts a methodology 700 for stacking dies in accordance with yet another embodiment of the disclosed subject matter. Methodology 700 can be employed, for example, where a multi-die stack includes a larger die (e.g., 104) that can be stacked above a smaller die (e.g., 102) in the die stack, where the smaller die can be smaller in size (e.g., length and/or width) than the larger die. At 702, the bottom sides of each die and DSM (e.g., DSM 112) that are to be included in or with the die stack can be laminated with die-attach film (e.g., die-attach film 108). For example, a bottom side (e.g., non-active side) of the first die (e.g., smaller die) and the bottom side (e.g., non-active side) of the second die (e.g., larger die) can be laminated with die-attach film. Further, the bottom side of a specified number of DSMs can be laminated with the film, where the DSMs can be employed to facilitate wirebonding of the dies and supporting the larger die. The number of DSMs to be employed and/or the dimensions of each of the DSMs can be determined, as described herein, for example, in accordance with device 200, device 100, and methodology 600.

At 704, the first die can be attached to a substrate (e.g., substrate 106) or another component (e.g., another die, DSM) using the die-attach film to facilitate the adhesion and/or attachment. At 706, wirebonding can be performed to attach a desired number of wires (e.g., wires 110) to the first die to electrically connect the first die to the substrate. For example, the top side of the first die can be the active side and can have pads thereon to which wires can be bonded. The desired number of wires can be bonded to the pads on the first die and the other ends of such wires can be attached to the substrate, for example.

At 708, the bottom side of each of the DSMs can be attached to the substrate or other component using the film to facilitate the attachment. For example, the DSMs can be positioned next to the first die and wires attached thereto such that the DSMs can provide the desired support to a larger die that can be placed directly above the first die in the multi-die stack in areas where the larger die overhangs when placed directly above the smaller first die, while also facilitating the wirebonding of the first die. To further illustrate, if the length of the larger second die is greater than the smaller die, for example, then two DSMs can be employed to support the second die in the areas where the length of the second die exceeds or extends beyond the length of the smaller die. At 710, the bottom side of the second die can be attached to the top sides of the DSMs using the film to facilitate the attachments. At 712, wirebonding can be performed to attach a desired number of wires to the second die to electrically connect the second die to the substrate. For example, the top side of the second die can be the active side and can have pads thereon to which wires can be bonded. The desired number of wires can be bonded to the pads on the second die and the other ends of such wires can be attached to the substrate, for example. At this point, methodology 700 can end.

It is to be appreciated that, while methodology 700 includes two dies, the disclosed subject matter is not so limited, and the number of dies are for purposes of example to demonstrate various aspects of the disclosed subject matter. Methodology 700 can include any desired number of dies and any desired number of DSMs to facilitate multi-die stacking in accordance with the disclosed subject matter.

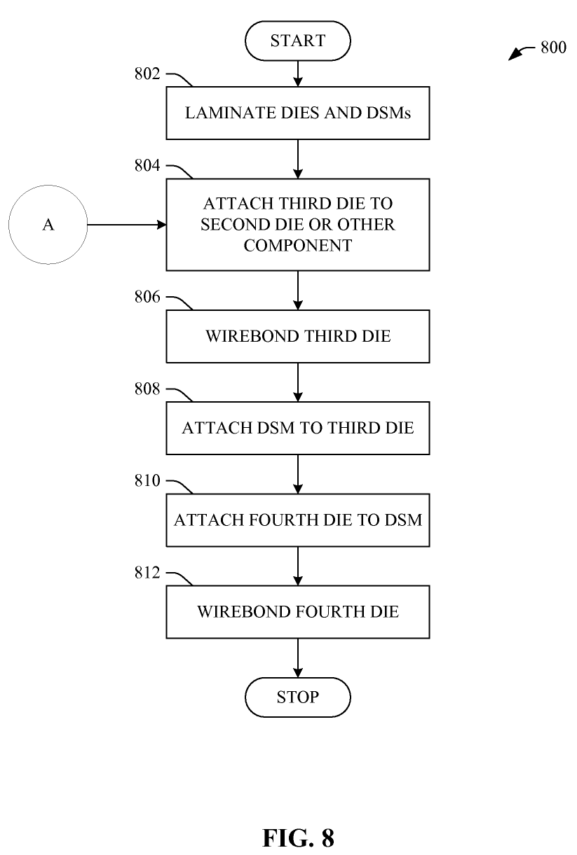

FIG. 8 illustrates a methodology 800 for stacking dies in accordance with an embodiment of the disclosed subject matter. Methodology 800 can be employed, for example, where a multi-die stack includes two dies of the same or similar size that are to be positioned one on top of the other in the die stack. In accordance with one embodiment of the disclosed subject matter, methodology 800 can begin at reference point A, which is the point where methodology 700 ended. At reference point A from methodology 700, a die stack can include a larger second die stacked directly above a smaller first die in a die stack. In accordance with another embodiment of the disclosed subject matter, methodology 800 can begin without regard to the methodology 700. It is to be appreciated that methodology 800 does require methodology 700 to be performed first, and methodology 800 can be performed independent of and without methodology 700, or before methodology 700 is performed, or after methodology 700 is performed.

At 802, a bottom side of a third die (e.g., 202), fourth die (e.g., 204), and a DSM (e.g., 112) can be laminated with die-attach film (e.g., film 108). The DSM can be employed to facilitate wirebonding of the third die and fourth die as well as to provide desired support to the fourth die to minimize or reduce overhang and bouncing of the fourth die. The dimensions of the DSM can be determined, as described herein, for example, in accordance with device 200, device 100, and methodology 600. It is to be appreciated that, if methodology 800 is continuing from reference point A of methodology 700, then the third die, fourth die, and DSM of methodology 800 optionally can be laminated with die-attach film at reference numeral 702, thereby obviating the actions associated with reference numeral 802, and methodology 800 can begin at 804.

At 804, the third die can be attached to the second die (e.g., 104) from reference point A with the die-attach film facilitating the adhesion and/or attachment. Alternatively, at 804, the third die can be attached to a substrate (e.g., 106) or another component (e.g., another die, DSM) with the film facilitating the adhesion and/or attachment.

At 806, wirebonding can be performed to attach a desired number of wires to the third die to electrically connect the third die to the substrate. For example, the top side of the third die can be the active side and can have pads thereon to which wires can be bonded. The desired number of wires can be bonded to the pads on the third die and the other ends of such wires can be attached to the substrate, for example.

At 808, the bottom side of the DSM can be attached to the top side of the third die with the film facilitating the adhesion and/or attachment. At 812, a bottom side of a fourth die can be laminated with film. At 810, the bottom side of the fourth die can be attached to the top side of the DSM with the film facilitating the adhesion and/or attachment. The fourth die can be the same or similar in size to the third die, for example. Further, the bottom side of the fourth die can be the non-active side of the fourth die.

At 812, wirebonding can be performed to attach a desired number of wires to the fourth die to electrically connect the fourth die to the substrate. For example, the top side of the fourth die can be the active side and can have pads thereon to which wires can be bonded. The desired number of wires can be bonded to the pads on the fourth die and the other ends of such wires can be attached to the substrate, for example. At this point, methodology 800 can end.

It is to be appreciated that the third die and fourth die are referred to as such in order to distinguish those dies from the first die and second die associated with methodology 700, and methodology 700 can be associated with methodology 800 at reference point A, for example. Referring to such dies of methodology 800 as the third die and fourth die is not intended to and does not require that methodology 800 be associated with four dies. It is also to be appreciated that, while methodology 800 includes two dies and one DSM, the disclosed subject matter is not so limited, and the number of dies and DSMs are for purposes of example to demonstrate various aspects of the disclosed subject matter. Methodology 800 can include any desired number of dies and any desired number of DSMs to facilitate multi-die stacking in accordance with the disclosed subject matter.

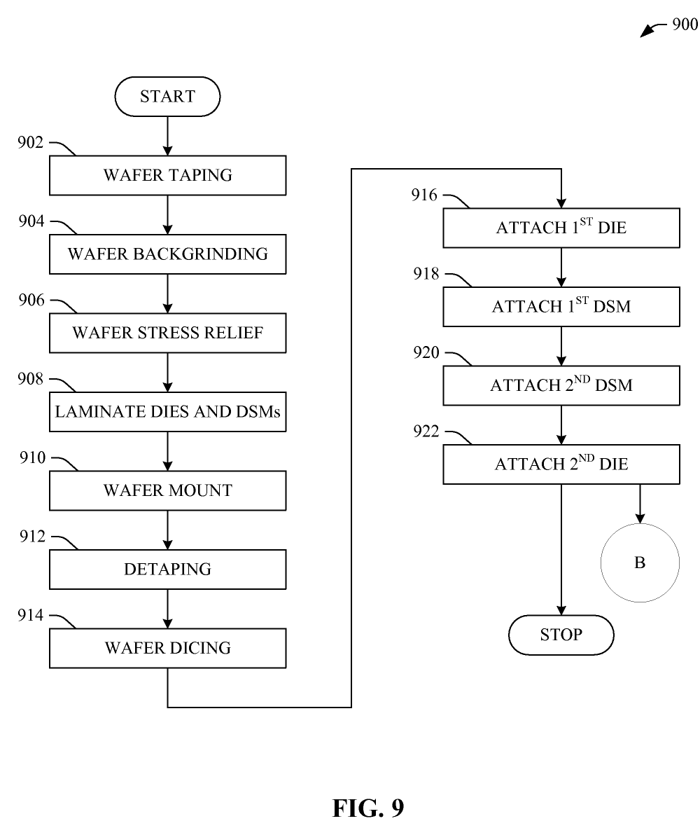

FIG. 9 depicts another methodology 900 for stacking dies in accordance with another embodiment of the disclosed subject matter. Methodology 900 can be employed, for example, where a multi-die stack includes a larger die (e.g., 104) that can be stacked above a smaller die (e.g., 102) in the die stack. At 902, one or more semiconductor wafers can be taped using conventional tape, such as backgrinding tape, that can be applied to the active side of each of the wafers, or if a wafer is a blank wafer that can be used to create DSM(s) (e.g., 112), then the tape can be applied to the side of the wafer that can be the top side of the DSM(s). For example, there can be a wafer for each active die that is to be included in a die stack as well as one or more wafers that can be utilized in creating DSMs. The taping of the wafers can be performed using a taping machine, for example. At 904, the wafers can be backgrinded by grinding each of the wafers on its non-active side, which can reduce the thickness of the wafer to a desired thickness. It should be noted that both the top side and the bottom side of the DSMs can be a non-active side. At 906, stress relief can be applied to each of the wafers in order to relieve stressed areas on each wafer, where the stressed areas may have damaged layers as a result of the backgrinding of the wafers.

At 908, the bottom sides, which can be the non-active sides, of each of the wafers can be laminated using die-attach film (e.g., die-attach film 108). The amount of film applied to each of the wafers can be such that it can facilitate adhering and/or attaching the dies and/or DSMs, which can be created from the wafers, to a substrate or other component (e.g., die, DSM) and the film can mold itself around traces and other uneven portions on the surface of the substrate or other component during attachment. For example, film having a thickness of thirty microns can be applied to the non-active side of the wafers.

At 910, each of the wafers can be mounted to a dicing tape. At 912, detaping can be performed to remove the tape applied to the wafers at 902. At 914, each of the wafers can be diced, as desired, to create one or more dies from the wafers as well as a desired number of DSMs. For example, a dicing saw can be utilized to dice each wafer into an active die or, if such wafer is blank, into one or more DSMs. At 916, a first die (e.g., first die 102) resulting from a diced wafer can be attached to the substrate (or another die or component) by placing the laminated first die on top of the substrate (or other die or component) with the die-attach film facilitating attaching the die to the substrate, in accordance with the disclosed subject matter.

At 918, the laminated side of a first DSM can be attached to the substrate or other component (e.g., another die or component) to which the first die is attached. The first DSM can be created as a result of dicing a blank wafer, for example. At 920, the laminated side of a second DSM can be attached to the substrate or other component (e.g., another die or component) to which the first die is attached. The second DSM can be created as a result of dicing a blank wafer, for example. For example, the first and second DSMs can be positioned next to the first die, and wires that can be bonded thereto, in regions where a larger second die will have overhang when placed directly above the first die on the die stack. The respective sizes and positions of the DSMs can be determined as described herein, for example, in accordance with device 200, device 100, and methodology 600.

At 922, a second die (e.g., second die 104) resulting from another diced wafer can be attached to the top sides of the first and second DSMs by placing the laminated side of the second die on top of the DSMs with the die-attach film facilitating adhering and/or attaching the second die to the DSMs, in accordance with the disclosed subject matter. At this point, methodology 900 can end.

It is to be appreciated that, while methodology 900 includes two dies and two DSMs, the disclosed subject matter is not so limited, and the number of dies and DSMs are for purposes of example to demonstrate various aspects of the disclosed subject matter. Methodology 900 can include any desired number of dies and any desired number of DSMs to facilitate multi-die stacking in accordance with the disclosed subject matter.

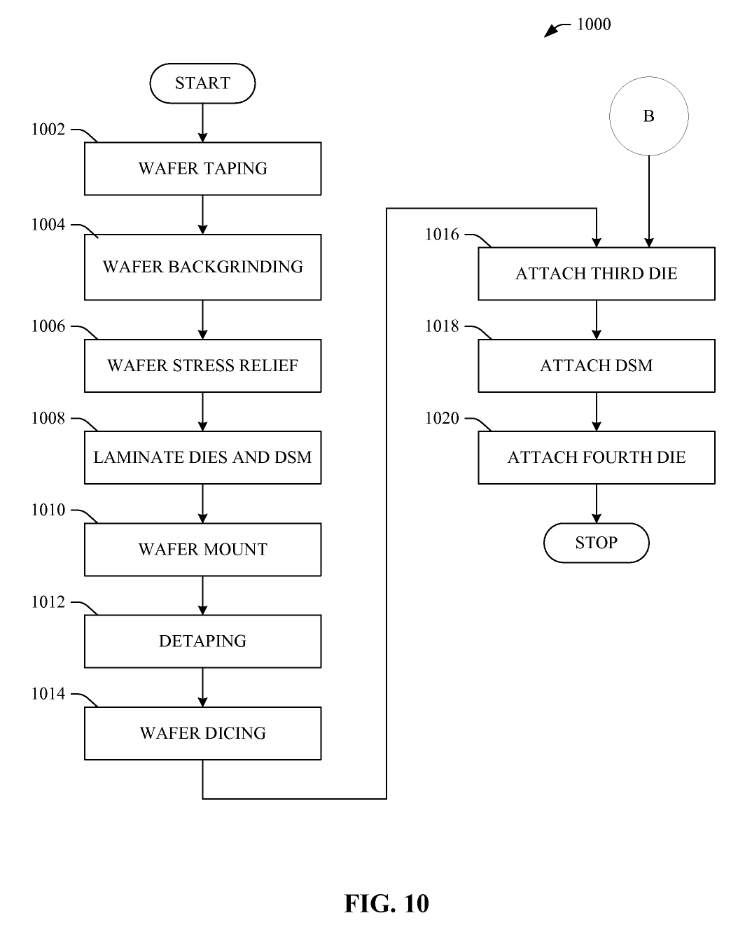

Referring to FIG. 10, another methodology 1000 for stacking dies in accordance with another embodiment of the disclosed subject matter is illustrated. Methodology 1000 can be employed, for example, where a multi-die stack includes two dies (e.g., 202, 204) of the same or similar size that are to be positioned one on top of the other in the die stack. In accordance with one embodiment of the disclosed subject matter, methodology 1000 can begin at reference point B, which is the point where methodology 900 ended. At reference point B from methodology 900, a die stack can include a larger second die (e.g., 104) stacked directly above a smaller first die (e.g., 102) in a die stack. In accordance with another embodiment of the disclosed subject matter, methodology 1000 can begin without regard to the methodology 900. It is to be appreciated that methodology 1000 does require methodology 900 to be performed first, and methodology 1000 can be performed independent of and without methodology 900, or before methodology 900 is performed, or after methodology 900 is performed.

At 1002, one or more semiconductor wafers can be taped using conventional tape, such as backgrinding tape, that can be applied to an active side of each of the wafers, or if a wafer is a blank wafer that can be used to create a DSM(s) (e.g., 112), then the tape can be applied to the side of the wafer that can be the top side of the DSM(s). For example, there can be a wafer for each active die that is to be included in a die stack as well as one or more wafers that can be utilized in creating DSMs. The taping of the wafer can be performed using a taping machine, for example. At 1004, each wafer can be backgrinded by grinding the wafer on its non-active side, which can reduce the thickness of the wafer to a desired thickness. At 1006, stress relief can be applied to each of the wafers in order to relieve stressed areas on each of the wafers, as a wafer may have damaged layers as a result of the backgrinding of the wafer. At 1008, the bottom side, which can be the non-active side, of each of the wafers can be laminated using die-attach film (e.g., film 108). The amount of film applied to each of the wafers, from which the dies and/or DSMs can be created, can be such that the film can facilitate attaching the wafer and/or the DSM to the substrate (e.g., 106) or other component (e.g., another die, such as second die 104) and the film can mold itself around traces and other uneven portions on the surface of the substrate or other component during attachment. For example, film having a thickness of thirty microns can be applied to the non-active side of each of the wafers.

At 1010, each of the wafers can be mounted to a dicing tape. At 1012, detaping can be performed to remove the tape applied to each of the wafers at 1002. At 1014, each of the wafers can be diced, as desired, to create one or more dies from the wafers as well as a desired number of DSMs. For example, a dicing saw can be utilized to dice each wafers into an active die or, if such wafer is blank, into one or more DSMs.

At 1016, a third die (e.g., third die 202) resulting from a diced wafer can be attached to the substrate (or another die (e.g., 104) or component) by placing the laminated third die on top of the substrate (or other die or component) with the die-attach film facilitating attaching the third die to the substrate (or other die or component), in accordance with the disclosed subject matter. It is to be appreciated that, according to one embodiment of the disclosed subject matter, methodology 1000 can continue from reference point B of methodology 900, where, for example, the die stack includes four dies (e.g., 102, 104, 202, 204). If methodology 1000 is continuing from methodology 900, then the acts described with regard to reference numerals 1002, 1004, 1006, 1008, 1010, 1012, and/or 1014 can be optional with regard to methodology 1000, as such acts can be performed on the wafers at reference numerals 902, 904, 906, 908, 910, 912, and/or 914, correspondingly, as part of methodology 900. In such instance, methodology 1000 can optionally begin at reference numeral 1016.

At 1018, the laminated side of the DSM can be attached to the top side of the third die. The DSM can be created by dicing a blank wafer, for example. At 1020, a fourth die (e.g., fourth die 204) resulting from a diced wafer can be attached to the DSM by placing the laminated side of the fourth die on top side of the DSM with the die-attach film facilitating attaching the fourth die to the DSM, in accordance with the disclosed subject matter. At this point, methodology 1000 can end.

It is to be appreciated that, while methodology 1000 includes two dies and one DSM, the disclosed subject matter is not so limited, and the number of dies and DSMs are for purposes of example to demonstrate various aspects of the disclosed subject matter. Methodology 1000 can include any desired number of dies and any desired number of DSMs to facilitate multi-die stacking in accordance with the disclosed subject matter.

As utilized herein, terms “component,” “system,” and the like can include a computer-related entity, either hardware, software (e.g., in execution), and/or firmware. For example, a component can be a process running on a processor, a processor, an object, an executable, a program, and/or a computer. By way of illustration, both an application running on a server and the server can be a component. One or more components can reside within a process and a component can be localized on one computer and/or distributed between two or more computers.

Although the subject innovation has been shown and described with respect to certain illustrated aspects, it will be appreciated that equivalent alterations and modifications will occur to others skilled in the art upon the reading and understanding of this specification and the annexed drawings. In particular regard to the various functions performed by the above described components (e.g., assemblies, devices, circuits, systems, etc.), the terms (including a reference to a “means”) used to describe such components are intended to correspond, unless otherwise indicated, to any component which performs the specified function of the described component (e.g., that is functionally equivalent), even though not structurally equivalent to the disclosed structure, which performs the function in the herein illustrative aspects of the disclosed subject matter. In this regard, it will also be recognized that the subject innovation can include a system as well as a computer-readable medium having computer-executable instructions for performing the acts and/or events of the various methods of the subject innovation.

What has been described above includes examples of aspects of the disclosed subject matter. It is, of course, not possible to describe every conceivable combination of components or methodologies for purposes of describing the disclosed subject matter, but one of ordinary skill in the art may recognize that many further combinations and permutations of the disclosed subject matter are possible. Accordingly, the disclosed subject matter is intended to embrace all such alterations, modifications and variations that fall within the spirit and scope of the appended claims. Furthermore, to the extent that the terms “includes,” “has,” or “having,” or variations thereof, are used in either the detailed description or the claims, such terms are intended to be inclusive in a manner similar to the term “comprising” as “comprising” is interpreted when employed as a transitional word in a claim.

What is claimed is:

1. A semiconductor device, comprising:
a first die that has an active side; and
die support mechanisms that facilitate wirebonding of the first die when a second die is stacked above the first die, the second die is a larger size, in at least one of length or width, or a combination thereof, as compared to the first die.

2. The device of claim 1, further comprising:
a substrate that has a plurality of traces formed thereon; and
a plurality of wires that are electrically connected correspondingly to the substrate and at least one of the first die and the second die, or a combination thereof.

3. The device of claim 2, the first die is attached to the substrate with a film such that there are no gaps between the first die and the substrate.

4. The device of claim 1, a bottom side of the second die is attached to the respective top sides of the die support mechanisms such that the second die is stacked above the first die, the die support mechanisms have a height such that there is a buffer region between the bottom side of the second die and a top portion of each of the plurality of wires connected to the first die.

5. The device of claim 4, each die support mechanism has a length and width such that the second die has no outside edges that overhang beyond the die support mechanisms and wirebonding of the first die is facilitated.

6. The device of claim 5, further comprising:
a third die that is attached to a top side of the second die, the attachment of the second die and third die is facilitated with the film, which is applied to a bottom side of the third die; and
a fourth die that is at least one of a same size or a similar size as the third die, a bottom side of the fourth die is attached to a top side of a die support mechanism with the film and a bottom side of the die support mechanism is attached to a top side of the third die with the film, and the die support mechanism has a length and width such that wirebonding of the third die is facilitated and the amount of overhang of the fourth die is small enough so that there is substantially no bounce during wirebonding of the fourth die.

7. An electronic product comprising the device of claim 1, the electronic product further comprising at least one of a computer, a personal digital assistant, a cellular phone, a digital phone, an answering machine, a video device, a television, a digital versatile diskplayer/recorder, a music player/recorder, an MP3 player, a digital recorder, a digital camera, a microwave oven, an electronic organizer, an electronic toy, an electronic game, a scanner, a reader, a printer, a copy machine, or a facsimile machine.

8. A system that facilitates formation of multiple die stacks, comprising:
a first die;
a second die that is larger in size in at least one of length or width, or a combination thereof, than the first die; and
at least two die support mechanisms that facilitate attachment of one or more wires to the first die and support of the second die when the second die is attached to the at least two die support mechanisms.

9. The system of claim 8, further comprising:
a die support generation component that analyzes the respective positions of at least the first die, the second die, the one or more wires, or a film, or a combination thereof; analyzes the respective dimensions of at least the first die, the second die, the one or more wires, or the film, or a combination thereof; calculates at least a number of die support mechanisms or respective dimensions of each die support mechanism, or a combination thereof; facilitates at least one wafer being cut into the at least two die support mechanisms; and facilitates generation of the at least two die support mechanisms.

10. The system of claim 8, a bottom side of the second die is attached to respective top sides of the at least two die support mechanisms and is positioned directly above the first die in the die stack.

11. The system of claim 10, the at least two die support mechanisms are positioned adjacent to the first die and one or more wires attached thereto, and each die support mechanism has a respective size such that the attachment of the one or more wires to the first die is facilitated and the second die has substantially no overhang beyond the at least two die support mechanisms and there is substantially no sag in the center of the second die.

12. The system of claim 8, the one or more wires are bonded to the first die and a substrate to electrically connect the first die and the substrate.

13. The system of claim 8, further comprising:
a third die; and
a fourth die that is substantially the same size as the third die, the die support generation component generates a die support mechanism that is attached to a bottom side of the fourth die and a top side of the third die, the die support mechanism has a size such that wirebonding of the third die and the fourth die is facilitated and the fourth die is supported so that there is substantially no bounce when wires are bonded to the fourth die.

14. A method for stacking multiple dies, comprising:
laminating the bottom of a die with a film; and
adhering the die to die support mechanisms that facilitate wirebonding of the die and wirebonding of another die that is positioned under the die in a multi-die stack, the die is larger in size than the other die.

15. The method of claim 14, further comprising:
analyzing a position of at least one of the die, the other die, one or more wires, the film, or a combination thereof;
analyzing dimensions of at least one of the first die, the other die, the one or more wires, or the film, or a combination thereof;
calculating a number of die support mechanisms;
calculating respective dimensions of each die support mechanism;
cutting at least one wafer; and
generating at least two die support mechanisms.

16. The method of claim 14, further comprising:
laminating the other die with the film;
adhering the other die to a substrate;
attaching one or more wires to the other die and the substrate to electrically connect the other die with the substrate;
laminating a bottom side of the at least two die support mechanisms with the film;
adhering a respective bottom side of each of the at least two die support mechanisms to the substrate.

17. The method of claim 14, further comprising:
attaching one or more wires to the die and the substrate to electrically connect the die with the substrate, a size of each of the at least two die support mechanisms is such that at least one of wirebonding of the die and wirebonding of the other die are facilitated, there is substantially no sagging in a center region of the die, or an outer edge of the die is substantially even with a respective outer edge of each of the at least two die support mechanisms, or a combination thereof.

18. The method of claim 14, further comprising:
taping at least one wafer;
backgrinding the at least one wafer;
applying stress relief to the at least one wafer;
mounting the at least one wafer; and
detaping the at least one wafer.

19. The method of claim 18, further comprising:
dicing the at least one wafer into at least one die.

20. The method of claim 18, further comprising:
dicing the at least one wafer into die support mechanisms.
